(19) United States
(12) Patent Application Publication
(10) Pub. No.: US 2026/0173926 A1
(43) Pub. Date: Jun. 18, 2026

(54) MEMORY DEVICE WITH MULTI-CONNECTION MECHANISM FOR COMBINATION PACKAGES

(71) Applicant: Micron Technology, Inc., Boise, ID (US)

(72) Inventors: Wen Wei Lum, Singapore (SG); Kelvin Tan Aik Boo, Singapore (SG); Ying Hsuan Lin, Taichung (TW); Hong Wan Ng, Singapore (SG)

(21) Appl. No.: 19/379,739

(22) Filed: Nov. 4, 2025

Related U.S. Application Data
(60) Provisional application No. 63/735,485, filed on Dec. 18, 2024.

(51) Int. Cl. H01L 23/538; H01L 23/00; H01L 23/498; H01L 25/18; H10B 80/00; H10D 80/30

(52) U.S. Cl. CPC H10W 70/65; H10B 80/00; H10D 80/30; H10W 70/611; H10W 90/00; H10W 90/701; H10W 90/754; H10W 90/794

(57) ABSTRACT

Semiconductor packaging device are described herein. In one embodiment, the device includes a substrate configured to support at least two types of Multi-Chip Package (MCP) configurations. One MCP configuration includes a Universal Flash Storage (UFS) memory controller, and another MCP configuration includes an embedded multi-media card (eMMC) controller. The substrate is configured through internal connections and signal assignments to support either of the UFS controller or the eMMC controller selected to be included in the final MCP.

### CROSS-REFERENCE TO RELATED APPLICATION(S)

The present application claims priority to U.S. Provisional Patent Application No. 63/735,485, filed Dec. 18, 2024, the disclosure of which is incorporated herein by reference in its entirety.

### TECHNICAL FIELD

The present disclosure is related to semiconductor devices, packages, and/or associated methods. In particular, the present disclosure is related to memory devices with configurable connection mechanism for combination packages.

### BACKGROUND

Memory devices are widely used to store information related to various electronic devices such as computers, wireless communication devices, cameras, digital displays, and the like. Memory devices are frequently provided as internal, semiconductor, integrated circuits and/or external removable devices in computers or other electronic devices. There are many different types of memory, including volatile and non-volatile memory and combination devices that include both volatile and non-volatile memory within one package. Volatile memory, including static random access memory (SRAM), dynamic random access memory (DRAM), and synchronous dynamic random access memory (SDRAM), among others, may require a source of applied power to maintain its data. Non-volatile memory, by contrast, can retain its stored data even when not externally powered. Non-volatile memory is available in a wide variety of technologies, including flash memory (e.g., NAND and NOR) phase change memory (PCM), ferroelectric random access memory (FeRAM), resistive random access memory (RRAM), and magnetic random access memory (MRAM), among others. Improving memory devices, generally, may include increasing memory cell density, increasing read/write speeds or otherwise reducing operational latency, increasing reliability, increasing data retention, reducing power consumption, increasing applicability, or reducing manufacturing costs, among other metrics.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1A is a perspective view of a system having a memory device configured in accordance with various embodiments of the present technology.

FIG. 1B is a connector map of the system configured in accordance with various embodiments of the present technology.

FIG. 2A is a perspective view of a system having a memory device configured in accordance with various embodiments of the present technology.

FIG. 2B is a connector map of the system configured in accordance with various embodiments of the present technology.

FIG. 2C is a perspective view of a system having a memory device configured in accordance with various embodiments of the present technology.

FIG. 3 is a flow diagram illustrating a method of manufacture in accordance with various embodiments of the present technology.

FIG. 4 is a schematic view of a system that includes a memory device in accordance with various embodiments of the present technology.

### DETAILED DESCRIPTION

As discussed in greater detail below, the technology disclosed herein relates to semiconductor systems and devices (and associated methods) having and/or facilitating memory circuits. For example, the semiconductor systems and devices can include package-on-packages (POPs) and/or multi-chip packages (MCPs) having the memory circuits therein. In some embodiments, the semiconductor systems and devices can include Universal Flash Storage (UFS) based MCPs (uMCPs) that correspond to UFS based POPs (uPOPs). The uMCPs can each have one or more UFS controllers along with memory circuits, such as dynamic random-access memory (DRAM) (e.g., Low Power Double Data Rate (LPDDR) DRAM devices), mounted on a top side of a package substrate. On the bottom side, the package substrate can have a set of connectors (e.g., solder balls) configured for package-external communications. The set of connectors can be configured to support a vertical stacking scheme, such as for a POP configuration.

To increase the flexibility of the supported the POP configuration, the semiconductor systems and devices can have a universal connector configuration or a multi-connection mechanism for further supporting different types of MCPs, such as embedded multi-media card (eMMC) based MCPs (eMCP). The eMCP can have one or more eMMC controllers along with memory circuits (e.g., LPDDR DRAM) mounted on the top side of the multi-connection package substrate. On the bottom side, the package substrate can have a set of connectors (e.g., solder balls) configured for package-external communications. The set of connectors can be configured (via, e.g., arrangement) to support both the eMCP and uMCP configurations. In other words, the semiconductor systems and devices can have the multi-connection configuration that can facilitate either the eMMC controller or the UFS controller along with the corresponding memory circuits (e.g., LPDDR5 by 16).

In some embodiments, the multi-connection configuration can correspond to a 8-by-9.5 package size with 0.35 pitch and have up to 201 connectors or pinouts. The connectors can be arranged in a rectangular ring shape, and each pin can be identified using a row location and a column location. The ring shape can correspond to two columns that correspond to outer peripheral portions and two rows that extend between the columns, one corresponding to a top peripheral portion of the ring and the other corresponding to a bottom portion of the ring. In one embodiment, the multi-connection configuration can have 21 columns (positions 1-21) and 25 rows that are represented by sequential alphabetic position identifiers (e.g., without ‘I’, ‘O’, ‘Q’, ‘S’, ‘X’, and ‘Z’, and including AA-AE). For such embodiment, the peripheral column portions can each include two columns (e.g., column positions 1, 2, 20, and 21), and the peripheral row portions can each include three rows (e.g., row positions A-C and AC-AE).

The multi-connection configuration can include a reference location that physically/visually provides a reference for the position identifiers. For example, the multi-connection configuration can include an empty spot at a predetermined location about the A1 position. In some embodiments, the reference location can be represented using an empty position in the ball grid, such as at C3, the bottom row within the top peripheral portion at the first column position outside of the peripheral columnar portions.

The multi-connection configuration can include a set of memory connectors configured to provide signal connections (e.g., inputs, outputs, power, ground, etc.) to the memory circuits. The memory connectors can be located on a lower portion of the peripheral columns and a lower one of the peripheral rows. In some embodiments, the memory connectors can be located for connectors located below or past a designated row (e.g., including row M and beyond/lower). Moreover, the memory connectors can be reflective about a middle column (e.g., column 11). For example, for a given row, the memory connectors located on columns 10 and 12 can be used to communicate the same or matching signals, and likewise matching signals on columns 9 and 13, on columns 8 and 14, and so forth.

Additionally, the multi-connection configuration can include the UFS controller connections for the positions in the top row portions (e.g., rows A-C) and between the peripheral row portions (e.g., column positions 3-19 between the peripheral positions 1-2 and 20-21). Further, the multi-connection configuration can have the connection shapes, assigned signal types, assigned signals, or a combination thereof mirror or match across a reference line.

Based on the features of the multi-connection configuration, the corresponding substrate and the external connectors can be used to support different types of packages. For example, the multi-connection configuration can be used to support an eMMC package that includes an eMMC controller instead of the UFS.

In addition to supporting multiple package types, the substrate having the multi-connection configuration for the external connectors can have an interleaved shielding configuration that assigns ground signals (e.g., VSSm) to connectors that are adjacent to and surrounding those assigned to one or more power signals (e.g., VCCm and/or VCCQm) and/or one or more targeted communication signals. Accordingly, the multi-connection configuration can provide improved signal integrity and power integrity (SIPI) metrics for the corresponding package. Further, based on one or more features of the multi-connection configuration, the corresponding package can have matching signal propagation lengths (e.g., based on the mirroring configuration) that provides improved signal performances, such as matching propagation times, noise levels, etc.

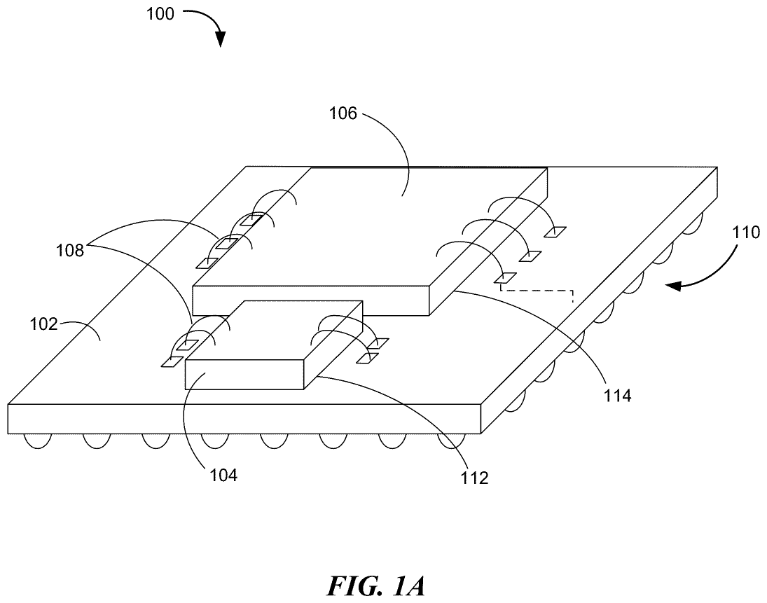

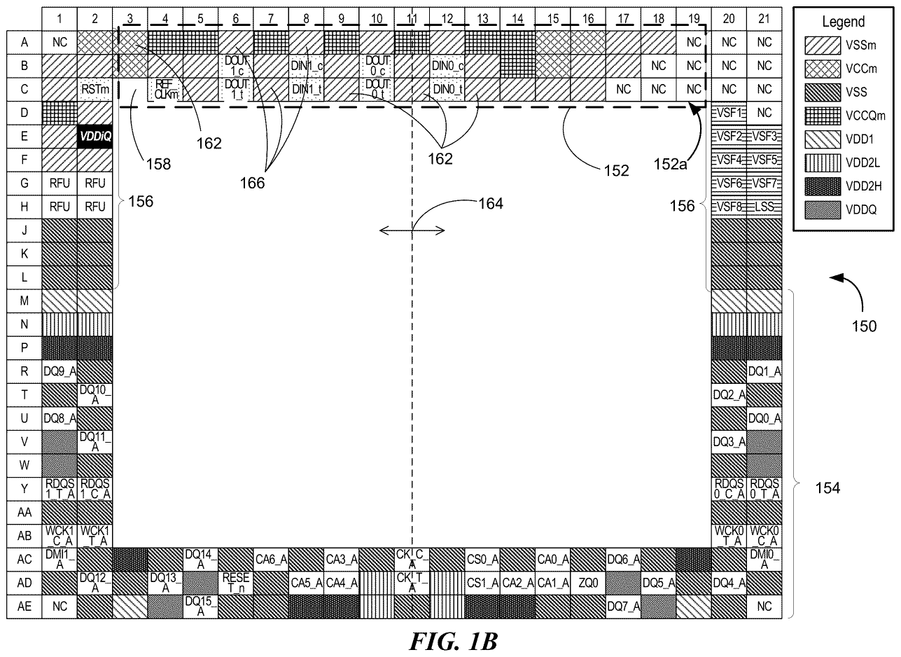

FIG. 1A is a perspective view of a system 100 having a memory device configured in accordance with various embodiments of the present technology. For example, the system 100 can include a uMPC corresponding to a uPOP configuration. The system 100 can include a substrate 102 with a UFS controller 104 and one or more memory circuits 106 (e.g., DRAM devices, such as LPDDR devices) mounted thereon. The UFS controller 104 and the memory circuits 106 can be communicatively coupled to the substrate 102 using top side connectors 108, such as wires, wirebonds, direct bonds, and/or the like. The internal connectors can be connected to pads on a top side of the substrate 102.

The substrate 102 can include a silicon structure, an epoxy- or a resin-based structure, a printed circuit board, or the like. The substrate 102 can include one or more internal connections (e.g., traces, vias, redistribution layer (RDL), and/or the like) that route signals to and/or from the UFS controller 104 and the memory circuits 106 across lateral and/or vertical directions. Using such substrate-internal connections, the substrate 102 can route signals/connections through a thickness thereof and to external connectors 110 on a bottom portion/side of the substrate. The external connectors 110 (e.g., solder balls) can be configured to communicatively couple the substrate 102, the UFS controller 104, and/or the memory circuits 106 to external devices. The external connectors 110 can be connected or formed on pads on the bottom side of the substrate 102.

The substrate 102 can include internal connections (shown using a dashed line in FIG. 1A), such as vias, traces, redistribution layers, or a combination thereof, configured to internally route the signal from the pads on the top side to pads on the bottom side and the corresponding external connectors 110. Accordingly, the substrate 102 can provide an electrically conductive path for each output from the mounted devices (e.g., the memory circuits 106 and the UFS controller 104) to the corresponding external connectors 110 through the pads and the internal connections.

In some embodiments, the substrate 102 can have a controller location 112 for designating placement of the UFS controller 104 and a memory location 114 for designating placement of the memory circuits 106. In other words, the UFS controller 104 can be mounted at the controller location 112 on a top portion/surface of the substrate 102, and the memory circuits 106 can be mounted at the memory location 114 on the top portion of the substrate 102.

FIG. 1B is a connector map (e.g., a multi-connection mechanism 150) of the system 100 of FIG. 1A configured in accordance with various embodiments of the present technology. The multi-connection mechanism 150 can represent signal assignments for the external connectors 110 of FIG. 1A.

In some embodiments, the multi-connection mechanism 150 can have the external connectors 110 arranged in a rectangular ring/donut shape. For the illustrated example, top and bottom lateral portions of the multi-connection mechanism 150 can each have three rows of connectors, and vertical/side portions can each include two columns that connect to the top and bottom portions. For illustrative purposes, the multi-connection mechanism 150 is shown using numeric column identifiers and alphabetic row identifiers. For the example of FIG. 1B, the row identifiers can be generally sequential with the exception of certain letters, such as ‘I’, ‘O’, ‘Q’, ‘S’, ‘X’, and ‘Z’. In some embodiments, the multi-connection mechanism 150 can have 25 rows and 21 columns (e.g., corresponding to uPOP 201 FBGA 21x25). Accordingly, the side vertical portions can correspond to columns 1-2 and 20-21, the top lateral portion can correspond to rows A-C, and the bottom lateral portion can correspond to rows AC-AE.

The multi-connection configuration 150 can designate or reserve portions of the external connectors 110 as controller connectors 152, memory connectors 154, and supplementary connectors 156. The controller connectors 152 can include the portion of the connectors 110 configured to provide communicative couplings with the UFS controller 104 of FIG. 1A. Accordingly, the controller connectors 152 for the system 100 of FIG. 1A can correspond to UFS connectors 152a that convey power, ground, and/or message signals to and/or from the UFS controller 104 of FIG. 1A. Further, the controller connectors 152 can be located about (e.g., within a threshold lateral distance away from) and/or directly under the controller location 112 of FIG. 1A. In the illustrated example, the controller connectors 152 can be a continuous/sequential set of connectors in the top lateral portion, such as for rows A-C and columns 3-19.

The memory connectors 154 can include the portion of the connectors 110 configured to provide communicative couplings with the memory circuits 106 of FIG. 1A. Accordingly, the memory connectors 154 can be located about, directly under and/or partially surrounding the memory location 114 of FIG. 1A. In the illustrated example, the memory connectors 154 can include the connectors 110 located below and including a boundary row (e.g., row ‘M’) for all columns, thereby having a ‘ [symbol] ’ shape.

The supplementary connectors 156 can include instances of the connectors 110 outside of the memory connectors 154 and the controller connectors 152. For the illustrated example, the supplementary connectors 156 can correspond to the connectors 110 in columns 1-2 and 20-21 and above row ‘M’ (e.g., rows A-N).

The multi-connection configuration 150 can further have a visual reference 158, such as a unique size/shape of a connector or a separation distance corresponding to the absence of a connector within a pattern of connectors, that identifies a predetermined pin location/identifier. For the illustrate example, the visual reference 158 can correspond to an increased separation distance along a lateral direction (e.g., corresponding to an absent solder ball at column 3, row C or “C3”) between columns 2 and 4 at row C. The visual reference 158 can visibly provide a reference for the connector identifiers by identify an upper left location for the connectors and/or the first pin (e.g., the connector at column 1, row A or “A1”).

To illustrate additional features, FIG. 1B illustrates example signal assignments for the multi-connection configuration 150. For example, the multi-connection configuration 150 illustrated in FIG. 1B can correspond to a ballout map for up to 201 pin out for a uMCP POP configuration. The illustrated ballout map can be for 8-by-9.5 package size with 0.35 pitch for the connectors 110.

In some embodiments, the additional features can include one or more common reference connectors 162. As described in further detail below, the multi-connection configuration 150 can be configured to support multiple package types, and the common reference connectors 162 can include connectors that are used to communicate the same signal across the multiple package types. For example, as further described below, the multi-connection configuration 150 can be configured to support a DRAM or an eMMC microcontroller (e.g., in place of the UFS controller 104), and the corresponding package may be an eMCP. The controller connectors 152 can include the common reference connectors 162, such as ground connections (VSSm) at predetermined ground locations (e.g., about the midpoint, such as at C9, C11, C13), power supply connections (VCCm) at predetermined system locations (e.g., about the visual indicator, such as at A3), power supply for controller at corresponding locations (e.g., A5), and the like. Two or more or all packaging configurations can communicate the same signal through the common reference connectors 162.

Additionally or alternatively, the multi-connection configuration 150 can further have a mirror configuration 164, an interleaved shielding configuration 166, or both. The mirror configuration 164 can have the connection shapes, assigned signal types, assigned signals, or a combination thereof mirror or match across a reference line, such as a middle position (e.g., column 11). For example, the UFS connectors 152a, the memory connectors 154 (e.g., LP5 pinout), or both can have matching types and/or signal names at locations mirroring across the middle position.

Moreover, the multi-connection configuration 150 can further have an interleaved shielding configuration 166 with ground signals/pins abutting or at least partially surrounding targeted connections, such as power signals or data signals. Accordingly, the ground signals can effectively function as a shield that prevents or reduces noise received and/or emitted by the surrounded connection.

The mirror configuration 164, the interleaved shielding configuration 166, or both can provide improved SIPI metrics for the multi-connection configuration 150 and the corresponding package. Moreover, the mirror configuration 164, the interleaved shielding configuration 166, or both can be leveraged to provide a signal-power to ground ratio closer to 1.0. Further, the mirror configuration 164, the interleaved shielding configuration 166, or both can provide better signal-interference (SI) performance with easier length matching (e.g., signal travel distances) and power delivery network connections to the memory circuits 106.

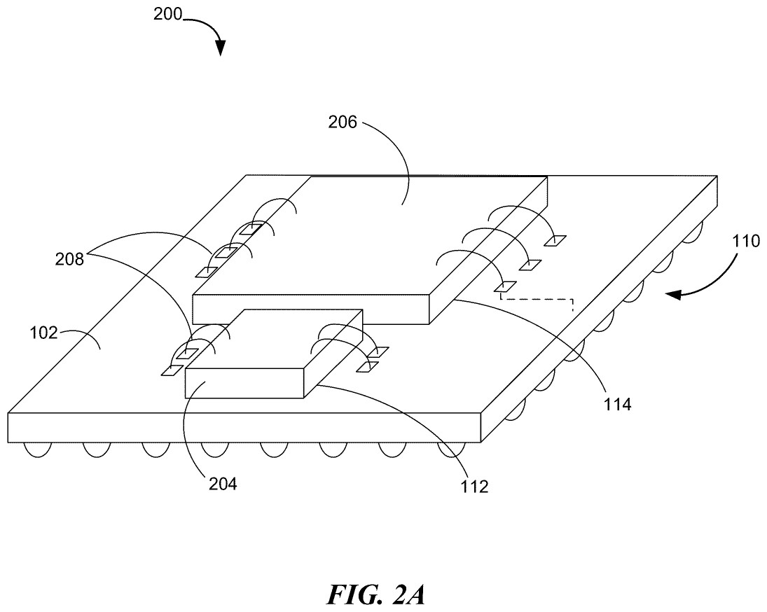

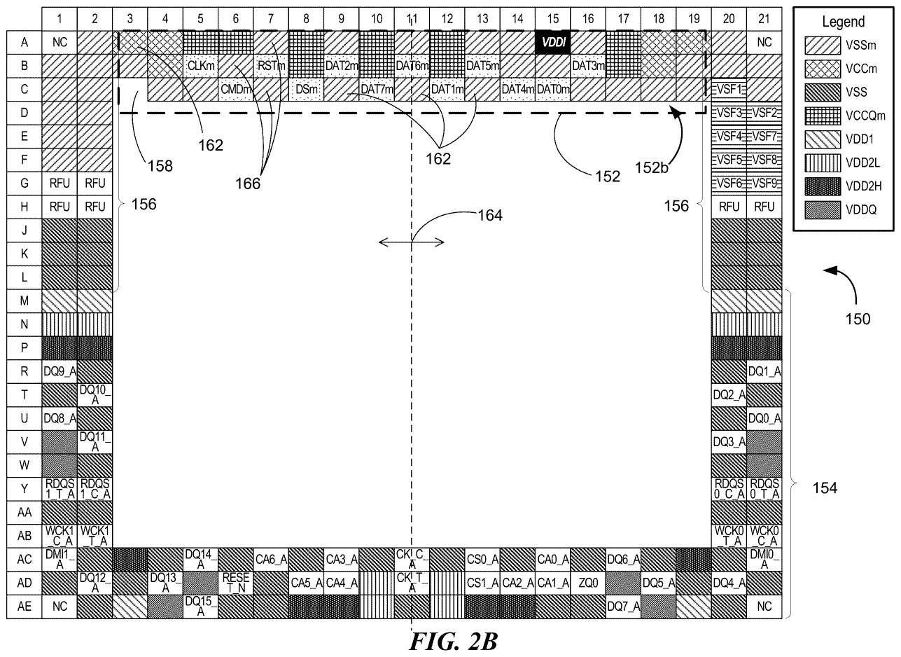

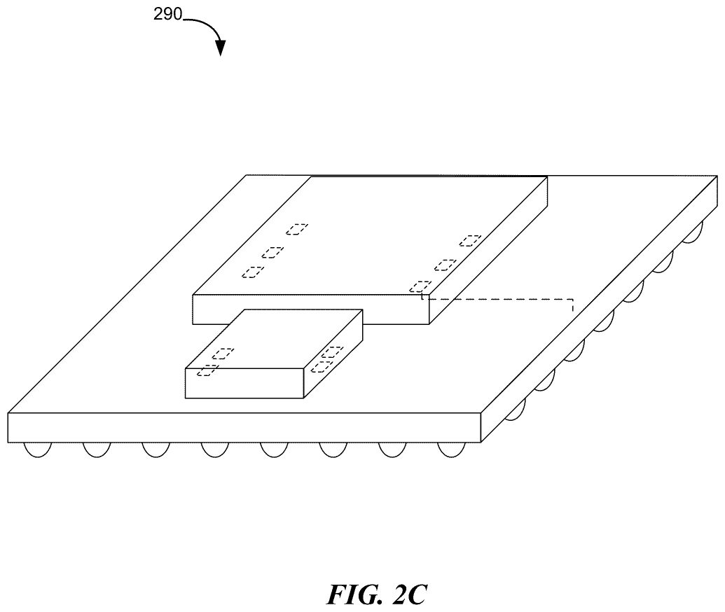

FIG. 2A is a perspective view of a system 200 having a memory device configured in accordance with various embodiments of the present technology. For example, the system 200 can include an eMPC corresponding to an ePOP configuration. The system 200 can include the substrate 102 with an eMMC controller 204 and one or more memory circuits 206 (e.g., DRAM devices, such as LPDDR devices) mounted thereon. The eMMC controller 204 and the memory circuits 206 can be communicatively coupled to the substrate 102 using internal connectors 208, such as wires, wirebonds, direct bonds, and/or the like.

The substrate 102 can include one or more internal connections (e.g., traces, vias, redistribution layer (RDL), and/or the like) that route signals to and/or from the eMMC controller 204 and the memory circuits 206 across lateral and/or vertical directions. Using such substrate-internal connections, the substrate 102 can route signals/connections through a thickness thereof and to the external connectors 110 on a bottom portion/side of the substrate. The external connectors 110 (e.g., solder balls) can be configured to communicatively couple the substrate 102, the eMMC controller 204, and/or the memory circuits 206 to external devices.

In some embodiments, the substrate 102 can have a controller location 212 for designating placement of the eMMC controller 104 and a memory location 214 for designating placement of the memory circuits 106. In other words, the eMMC controller 204 can be mounted at the controller location 212 on a top portion/surface of the substrate 102, and the memory circuits 206 can be mounted at the memory location 214 on the top portion of the substrate 102. The controller location 212 can at least partially overlap with the controller location 112 of FIG. 1A, and the memory location 214 can at least partially overlap with the memory location 114 of FIG. 1A.

FIG. 2B is a connector map (e.g., the multi-connection mechanism 150) of the system 200 of FIG. 2A configured in accordance with various embodiments of the present technology. The multi-connection mechanism 150 can represent signal assignments for the external connectors 110 of FIG. 1A. As described above, the multi-connection mechanism 150 can be configured to facilitate the UFS controller 104 of FIG. 1A for the system 100 of FIG. 1A as well as the eMMC controller 204 of FIG. 2A for the system 200.

The multi-connection mechanism 150 can have the external connectors 110 arranged in a rectangular ring/donut shape. The physical arrangement of the external connectors 110 (e.g., number of rows/columns, sizing, pitch, identification scheme, etc.) can be the same across the system 200 and the system 100.

The controller connectors 152 within the multi-connection configuration 150 can be used to provide communicative couplings with the eMMC controller 204 of FIG. 2A (e.g., instead of or in place of the UFS controller 104 of FIG. 1A). Accordingly, the controller connectors 152 for the system 200 of FIG. 2A can correspond to eMMC connectors 152b that convey power, ground, and/or message signals to and/or from the eMMC controller 204 of FIG. 2B. Further, the controller connectors 152 can be located about (e.g., within a threshold lateral distance away from) and/or directly under the controller location 212 of FIG. 2A.

The memory connectors 154 can include the portion of the connectors 110 configured to provide communicative couplings with the memory circuits 206 of FIG. 2A. Accordingly, the memory connectors 154 can be located about, directly under and/or partially surrounding the memory location 214 of FIG. 2A. In the illustrated example, the memory connectors 154 can include the connectors 110 located below and including a boundary row (e.g., row ‘M’) for all columns, thereby having a ‘ [symbol] ’ shape. In some embodiments, the memory circuits 206 and the memory circuits 106 can include same type of memory circuits (e.g., DRAM circuits, such as LPDDR devices).

The multi-connection configuration 150 can further include the supplementary connectors 156, the visual reference 158, the common reference connectors 162, or a combination thereof. Moreover, the multi-connection configuration 150 can have the signal assignments corresponding to the mirror configuration 164, the interleaved shielding configuration 166, or both.

To illustrate additional features, FIG. 1B illustrates example signal assignments for the multi-connection configuration 150. For example, the multi-connection configuration 150 illustrated in FIG. 1B can correspond to a ballout map for up to 201 pin out for a eMCP POP configuration (e.g., ePOP 201 FBGA 21x25). The illustrated ballout map can be for 8-by-9.5 package size with 0.35 pitch for the connectors 110. Accordingly, the substrate 102 having the multi-connection configuration 150 can be used to support or manufacture both the system 100 (e.g., uPOP) and the system 200 (ePOP).

For illustrative purposes, the system 100 of FIG. 1A and the system 200 of FIG. 2A have been described using wirebond type devices. However, it is understood that described technology can be implemented differently. For example, FIG. 2C is a perspective view of a system 290 having a memory device configured in accordance with various embodiments of the present technology. The system 290 can include (1) a uMPC corresponding to a uPOP configuration based on the multi-connection mechanism 150 of FIG. 1B or (2) an eMPC corresponding to an ePOP configuration based on the multi-connection mechanism 150 of FIG. 2B. However, instead of the wirebond type devices, the system 290 can have Direct Chip Attach (DCA) type devices. Accordingly, the system 290 can have a corresponding controller and/or corresponding memory circuits implemented as flip-chips mounted directly to the substrate. Instead of wirebonds, the connectors 108/208 can be implemented as solder bumps that are attached to pads overlapped by the devices.

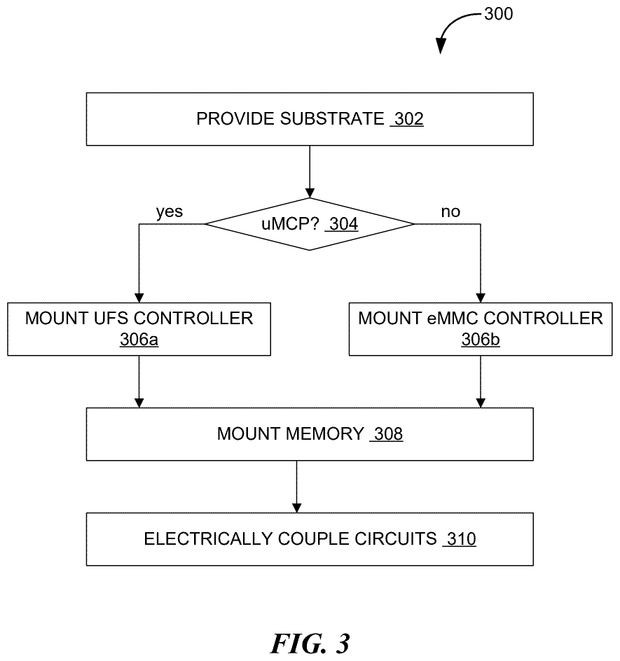

FIG. 3 is a flow diagram illustrating a method 300 of manufacture in accordance with various embodiments of the present technology. One or more portions of the method 300 can be implemented to manufacture the substrate 102 of FIG. 1, the MCP device (e.g., the system 100 of FIG. 1A or the system 200 of FIG. 2A), or a combination thereof.

The method 300 can include providing a substrate (e.g., the substrate 102) as shown in block 302. The provided substrate can include pads on the top side and the bottom side. The pads on the top side can include (1) a first set of pads configured to couple to a memory controller (e.g., the UFS controller 104 of FIG. 1A or the eMMC controller 204 of FIG. 2A) and (2) a second set of pads configured to couple to a memory device (e.g., the memory circuits 106 of FIG. 1A, the memory circuits 206 of FIG. 2A, etc.). The provided substrate can further include pads corresponding to the external connectors 110 of FIG. 1A on the bottom side.

Further, the provided substrate can include internal connections that couple the pads on the top side to corresponding pads on the bottom side. The internal connections can be configured to support the two different package types that correspond to the different controllers and the associated signal assignments. Effectively, the same substrate 102 can allow the manufacturer to mount either of the different controllers based on the internal connections and the signal assignments.

In some embodiments, providing the substrate 102 can include manufacturing the substrate 102. For example, manufacturing the substrate 102 can include providing a substrate body, such as a semiconductor substrate, an interposer structure, a printed circuit board structure, and/or the like. Manufacturing the substrate can further include forming the internal connections, such as by forming vias, traces, redistribution layers, or a combination thereof. Based on forming the internal connections, the manufacturing process can include forming the pads on the top side and the bottom side. The substrate manufacturing process can include leverage various processing steps, such as masking, etching, metallization, layer depositing, or a combination thereof, to form the components.

As illustrated at decision block 304, the method 300 can include selecting a packaging configuration. For example, the manufacturer can determine whether to manufacture a uMCP device using the substrate 102.

The method 300 can include mounting a controller according to the selection. For example, when the uMCP is selected as illustrated at block 306a, the method can include mounting a UFS controller (e.g., the UFS controller 104) at the controller location 112 of FIG. 1 on the top side of the substrate 102. Also, when the uMCP is not selected as illustrated at block 306b, the method can include mounting an eMMC controller (e.g., the eMMC controller 204) at the controller location 112.

As illustrated at block 308, the method 300 can include mounting memory circuits, such as LPDDR devices. For example, the memory circuits 106/206 can be mounted at the memory location 114.

In some embodiments, the method 300 can include electrically coupling the mounted devices to the substrate, such as using the top side connectors 108 (e.g., wire bonds). For example, the wire bonds can be formed connecting (1) the selected/mounted controller to a first set of pads and (2) the LPDDR5 devices to a second set of pads.

### Overall System

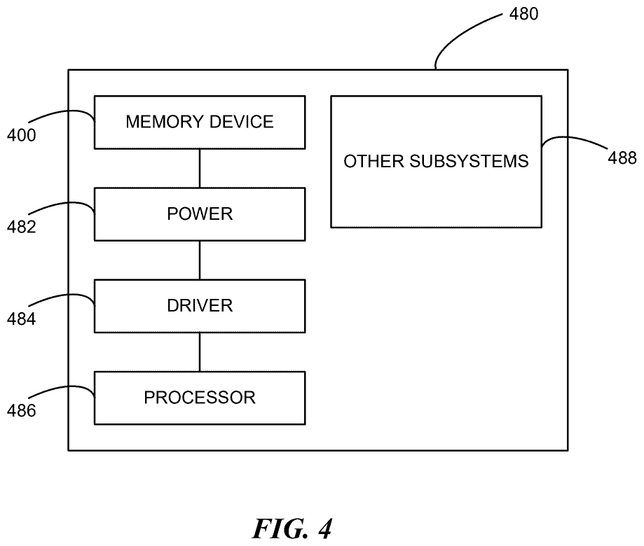

FIG. 4 is a schematic view of a system that includes an apparatus in accordance with embodiments of the present technology. Any one of the foregoing apparatuses (e.g., memory devices) described above with reference to FIGS. 1A-3 can be incorporated into any of a myriad of larger and/or more complex systems, a representative example of which is system 480 shown schematically in FIG. 4. The system 480 can include a memory device 400, a power source 482, a driver 484, a processor 486, and/or other subsystems or components 488. The memory device 400 can include features generally similar to those of the apparatus described above with reference to one or more of the FIGS, and can therefore include various features for performing a direct read request from a host device. The resulting system 480 can perform any of a wide variety of functions, such as memory storage, data processing, and/or other suitable functions. Accordingly, representative systems 480 can include, without limitation, hand-held devices (e.g., mobile phones, tablets, digital readers, and digital audio players), computers, vehicles, appliances and other products. Components of the system 480 may be housed in a single unit or distributed over multiple, interconnected units (e.g., through a communications network). The components of the system 480 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of NAND Flash devices. Apparatuses configured in accordance with other embodiments of the present technology, however, can include other types of suitable storage media in addition to or in lieu of NAND Flash devices, such as, devices incorporating NOR-based non-volatile storage media (e.g., NAND flash), magnetic storage media, phase-change storage media, ferroelectric storage media, dynamic random access memory (DRAM) devices, etc.

The term “processing” as used herein includes manipulating signals and data, such as writing or programming, reading, erasing, refreshing, adjusting or changing values, calculating results, executing instructions, assembling, transferring, and/or manipulating data structures. The term data structure includes information arranged as bits, words or code-words, blocks, files, input data, system-generated data, such as calculated or generated data, and program data. Further, the term “dynamic” as used herein describes processes, functions, actions or implementation occurring during operation, usage, or deployment of a corresponding device, system or embodiment, and after or while running manufacturer's or third-party firmware. The dynamically occurring processes, functions, actions or implementations can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to one or more of the FIGS. described above.

I/We claim:

1. A semiconductor package, comprising:
a substrate having a top side and a bottom side, the substrate having external connectors on the bottom side corresponding to a Package-On-Package (POP) Ballout configuration;
a Universal Flash Storage (UFS) memory controller mounted on the top side and communicatively coupled to the substrate; and
a Low Power Double Data Rate 5 (LPDDR) memory device mounted on the top side and communicatively coupled to the substrate.

2. The semiconductor package of claim 1, wherein the substrate is configured for a package size having a first lateral dimension of 8.0 millimeter and a second lateral dimension of 9.5 millimeter, wherein the first lateral dimension is orthogonal to the second lateral dimension.

3. The semiconductor package of claim 2, wherein the substrate has 201 external connectors that are arranged according to:
0.35 millimeter pitch, wherein adjacent ones of the external connectors are separated by 0.35 millimeter; and
a rectangular annulus having (1) three top rows of the connectors for a top lateral portion, (2) three bottom rows of the connectors for a bottom lateral portion, (3) two left columns of the connectors for a first vertical portion, and (4) two right columns of the connectors for a second vertical portion.

4. The semiconductor package of claim 3, wherein the rectangular annulus arrangement of the external connectors corresponds to 21 columnar positions and 25 row positions.

5. The semiconductor package of claim 3, wherein:
the top side of the substrate has a controller mounting location and a memory mounting location, wherein the UFS memory controller is mounted directly on the controller mounting location and the LPDDR5 memory device is mounted directly on the memory mounting location;
the external connectors in the top lateral portion of the rectangular annulus arrangement are closer to the controller mounting location than the memory mounting location and are configured to communicate signals to and/or from the UFS memory controller; and
the external connectors in the bottom lateral portion and at least bottom halves of the first and second vertical portions are closer to the memory mounting location than the controller mounting location and are configured to communicate signals to and/or from the LPDDR5 memory device.

6. The semiconductor package of claim 5, wherein the controller mounting location, the memory mounting location, and the corresponding communication assignments for the external connectors of the substrate further supports to a different packaging configuration that includes an embedded multi-media card (eMMC) controller instead of the UFS controller.

7. The semiconductor package of claim 5, wherein the rectangular annulus arrangement of the external connectors includes an extended separation between a connector in second column third row and a connector in fourth column-third row, wherein a portion of the bottom side of the substrate corresponding to third column-third row remains uncovered to represent a reference location for the external connectors.

8. The semiconductor package of claim 5, wherein the external connectors in the bottom lateral portion and at least bottom halves of the first and second vertical portions are configured to carry matching signals that mirror across a midpoint.

9. The semiconductor package of claim 5, wherein the external connectors include a set of ground pins that are interleaved between and surround power pins and/or signal pins along lateral directions.

10. A device, comprising:
a substrate body having a top side and a bottom side, wherein the substrate is configured to support a 8.0 millimeter by 9.5 millimeter multi-chip package (MCP);
a first set of pads on the top side, the first set of pads configured to couple to a controller attached to a controller location on the top side;
a second set of pads on the top side, the second set of pads configured to couple to Low Power Double Data Rate 5 (LPDDR5) memory circuits attached to a memory location on the top side;
internal connections extending from the first and second pads on the top side to the bottom side;
a set of external connectors on the bottom side and electrically connected to the internal connections,
wherein the set of external connectors are electrically coupled to the first and second set of pads and arranged in a rectangular annular arrangement according to a Package-On-Package (POP) ballout configuration,
wherein each connector within the set of external connectors is configured through the internal connections and signal assignments to communicate one of (1) a first signal to and/or from a Universal Flash Storage (UFS) memory controller electrically coupled to the first set of pads and (2) a second signal to and/or from an embedded multi-media card (eMMC) controller electrically coupled to the first set of pads.

11. The device of claim 10, wherein:
the set of external connectors includes 201 solder connections that are arranged according to 21 columnar positions and 25 row positions with 0.35 millimeter pitch; and
the rectangular annular arrangement includes (1) two columns extending vertically at each at left and right peripheral portions of the rectangular annular arrangement and (2) three rows each at top and bottom portions of the rectangular annular arrangement and extending between the left and right portions.

12. The device of claim 11, wherein the signal arrangements include:
the top portion of the rectangular annular arrangement coupled to the first set of pads; and
the bottom portion of the rectangular annular arrangement and bottom segments of the left and right portions of the rectangular annular arrangement coupled to the second set of pads.

13. The device of claim 12, wherein the signal arrangements for the second set of pads mirror across a vertical middle line between the left and right portions.

14. The device of claim 12, further comprising:
the LPDDR5 memory circuits mounted on the top side and electrically coupled to the second set of pads.

15. The device of claim 14, further comprising:
the eMMC controller mounted on the top side and electrically coupled to the first set of pads.

16. The device of claim 14, further comprising:
the UFS controller mounted on the top side and electrically coupled to the first set of pads.

17. The device of claim 11, wherein the rectangular annular arrangement includes a reference position configured to visually communicate the signal assignments based on leaving a position in a left-most column of the top portion of the rectangular annular arrangement unoccupied by a connector.

18. The device of claim 11, wherein the signal arrangements include a shielding configuration having ground connections surrounding one or more data pins, one or more power pins, or a combination thereof.

19. A 8.0 millimeter by 9.5 semiconductor (8x9.5) package, comprising:
a substrate having a top side and a bottom side and internal connections configured to route signals across the top and bottom sides;
Low Power Double Data Rate 5 (LPDDR) memory devices mounted on the top side and communicatively coupled to a second portion of the internal connections;
201 external connectors on the bottom side corresponding to a Package-On-Package (POP) Ballout configuration, wherein the 201 external connectors include (1) memory connectors connected to the second portion of the internal connections and the LPDDR memory devices and (2) controller connectors connected to a first portion of the internal connections and configured to support two pin assignments corresponding to (1) having a Universal Flash Storage (UFS) memory controller attached on the top side and coupled to the first portion of the internal connections and (2) having an embedded multi-media card (eMMC) controller attached on the top side and coupled to the first portion of the internal connections.

20. The package of claim 19, further comprising:
the UFS memory controller mounted on the top side and communicatively coupled to the first portion of the internal connections.
